(19) United States
(12) Patent Application Publication
(10) Pub. No.: US 2025/0217619 A1
(43) Pub. Date: Jul. 3, 2025

(54) Layer-Based Analog Hardware Realization of Neural Networks

(71) Applicant: PolyN Technology Limited, Bristol (GB)

(72) Inventors: Dmitrii GODOVSKII, Bucharest (RO); Boris Maslov, Palmetto, FL (US); Aleksandrs Timofejevs, Riga (LV)

(21) Appl. No.: 18/401,256

(22) Filed: Dec. 29, 2023

(51) Int. Cl. G06N 3/04; H01C 1/16; H03F 3/16

(52) U.S. Cl. CPC G06N 3/04; H01C 1/16; H03F 3/16

(57) ABSTRACT

Systems, devices, integrated circuits, and methods are provided for layer-based analog hardware realization of neural networks. An electronic device includes a collection of resistors, a collection of amplifiers, and a controller. The controller is configured to implement each of the plurality of layers sequentially. For each of the plurality of layers, the controller extracts, from memory, a plurality of layer parameters corresponding to a plurality of weights of the respective layer, and in accordance with the plurality of layer parameters, selects a plurality of resistors and a plurality of amplifiers and forms a set of input resistors from the plurality of resistors. The set of input resistors are electrically coupled to the plurality of amplifiers to form a neural layer circuit. The neural layer circuit may obtain a plurality of input signals via the plurality of resistors and generate a plurality of output signals from the plurality of input signals.

### TECHNICAL FIELD

The disclosed embodiments relate generally to electronic circuits, and more specifically to systems and methods for hardware realization of neural networks.

### BACKGROUND

Conventional hardware has failed to keep pace with innovation in neural networks and the growing popularity of machine learning based applications. The complexity of neural networks continues to outpace computational power of state-of-the-art processors as digital microprocessor advances are plateauing. Neuromorphic processors based on spike neural networks, such as Loihi and True North, are limited in their applications. For GPU-like architectures, the power and speed of such architectures are limited by data transmission speed. Data transmission can consume up to 80% of chip power and can significantly impact the speed of calculations. Edge applications demand low power consumption, but there are currently no known performant hardware embodiments that consume low power (e.g., less than 50 milliwatts).

Additionally, a training process required for neural networks presents unique challenges for hardware realization of neural networks. A trained neural network is used for specific inferencing tasks, such as classification. Once a neural network is trained, a hardware equivalent is manufactured. When the neural network is retrained, the hardware manufacturing process is repeated to provide brand-new hardware, which inevitably drives up hardware costs for analog realization of neural networks. Although some reconfigurable hardware solutions exist, such hardware cannot be easily mass produced, and costs a lot more (e.g., five times more) than hardware that is not reconfigurable. It would be beneficial to have a more efficient reprogramming mechanism for analog hardware realization of neural networks than the current practice.

### SUMMARY

Accordingly, there is a need for methods, systems, devices, circuits, and/or interfaces that address at least some of the deficiencies identified above and provide an efficient reprogramming mechanism for analog hardware realization of neural networks that is better than the current practice (e.g., re-manufacturing an entire chip after retraining of a neural network). Analog circuits have been modelled and manufactured to realize trained neural networks, which provide improved performance per watt compared with digital realization using arithmetic units and registers. Specifically, each layer of a neural network is implemented in a neural layer circuit using a plurality of resistors and a plurality of amplifiers. The plurality of resistors corresponds to a plurality of weights of the respective layer of the neural network. At least one of the plurality of resistors corresponds to a respective weight of the respective layer of the neural network. In some embodiments, the at least one resistor has variable resistance that is adjusted based on one of a plurality of mechanisms. As the neural layer circuit is reused to implement a distinct layer of the same neural network, the respective weight corresponding to the at least one resistor has a different value, and the variable resistance of the at least one resistor is adjusted to track the different value of the respective weight, thereby realizing different layers of the neural network based on the same hardware realization without duplicating the corresponding neural layer circuit on the same substrate of a neural network circuit that implements the neural network.

Many embodiments do not require hardware re-programmability across the entire hardware realization (e.g., the entire chip) of a neural network, particularly in edge environments where smart-home applications are applied. On-chip learning only impacts a small portion (e.g., 10%) of the hardware realization of a neural network, while a large portion (e.g., 90%) of hardware realization of the neural network remains the same without any changes of resistance values of resistors. Stated another way, in some embodiments, only a limited number of resistors of an analog realization of a neural network correspond to the small portion of the hardware realization impacted by on-chip learning and need to be adjusted after retraining of the neural network during the chip lifetime, which can be conveniently implemented using efficient resistance adjustment mechanisms without requiring the entire analog realization to be re-modelled and manufactured.

Additionally, in some embodiments, hardware realization of each layer of the neural network corresponds to a respective combination of resistance values of resistors, and the combination of resistance values of resistors varies among different layers of the analog realization of the trained or re-trained neural network. The neural network is fragmented into individual layers. A single neural layer circuit is successively applied to implement two or more different neural layers of the analog realization of the neural network using efficient resistance adjustment mechanisms based on the combinations of resistance values of resistors of these different neural layers. By these means, a neural network includes a total number of neural layers and is implemented by a limited number of neural layer circuits, where the limited number is less than the total number, thereby conserving the footprint of the analog realization of the neural network on a substrate of an electronic device and enhancing cost efficiency of the hardware realization of the neural network.

In one aspect, a method is applied to implement a neural network. The method includes sequentially implementing each of a plurality of layers of a neural network using a collection of resistors and a collection of amplifiers. Implementation of each of the plurality of layers further includes extracting, from memory, a plurality of layer parameters corresponding to a plurality of weights of the respective layer. Implementation of each of the plurality of layers further includes in accordance with the plurality of layer parameters, selecting a plurality of resistors from the collection of resistors, selecting a plurality of amplifiers electrically coupled to the plurality of resist from the collection of amplifiers, and forming a set of input resistors from the plurality of resistors. The set of input resistors is electrically coupled to the plurality of amplifiers to form a neural layer circuit. In some embodiments, implementation of each of the plurality of layers further includes obtaining a plurality of input signals for the neural layer circuit via the plurality of resistors and generating, by the neural layer circuit, a plurality of output signals from the plurality of input signals.

In some embodiments, the plurality of layers includes a first layer and a second layer. Forming the set of input resistors for each of the plurality of layers further includes selecting a first subset of resistors from the collection of resistors to form the set of input resistors of the first layer and selecting a second subset of resistors from the collection of resistors the set of input resistors of the second layer.

In some embodiments, the plurality of resistors is selected from a crossbar array of resistive elements having a plurality of word lines, a plurality of bit lines, and a plurality of resistive elements. Each resistive element is located at a cross point of, and electrically coupled between, a respective word line and a respective bit line.

In another aspect of this application, an electronic device includes a collection of resistors, a collection of amplifiers coupled to the collection of resistors, and a controller coupled to the collection of resistors and the collection of amplifiers. The controller is configured to implement each of the plurality of layers sequentially according any of the above methods.

In yet another aspect of this application, an integrated circuit includes a collection of resistors, a collection of amplifiers coupled to the collection of resistors, and a controller coupled to the collection of resistors and the collection of amplifiers. The controller is configured to implement each of the plurality of layers sequentially according any of the above methods.

Thus, methods, systems, and devices are disclosed that are used for hardware realization of trained neural networks.

### BRIEF DESCRIPTION OF THE DRAWINGS

For a better understanding of the aforementioned systems, methods, and devices, as well as additional systems, methods, and devices that provide analog hardware realization of neural networks, reference should be made to the Description of Embodiments below, in conjunction with the following drawings in which like reference numerals refer to corresponding parts throughout the figures.

FIG. 1A is a block diagram of a system for hardware realization of trained neural networks using analog components, according to some embodiments.

FIG. 1B is a block diagram of an alternative representation of the system of FIG. 1A for hardware realization of trained neural networks using analog components, according to some embodiments.

FIGS. 2A, 2B, and 2C are examples of trained neural networks that are input to a system and transformed to mathematically equivalent analog networks, according to some embodiments.

FIG. 3 shows an example of a mathematical model for a neuron, according to some embodiments.

FIG. 4 is a schematic diagram of an example neuron circuit for a neuron of a neural network used for resistor quantization, according to some embodiments.

FIG. 5 is a schematic diagram of an example operational amplifier, according to some embodiments.

FIG. 6A is a structural diagram of an example neural layer of a neural network, according to some embodiments.

FIG. 6B is a block diagram of an example neural layer circuit that implements the neural layer in FIG. 6A, according to some embodiments.

FIG. 7 is a schematic diagram of an example neural layer circuit for implementing a neural layer based on a crossbar array of resistive elements, according to some embodiments.

FIG. 8 is a diagram illustrating an example process of implementing an example neural network using a neural layer circuit, according to some embodiments.

FIG. 9 is a diagram illustrating an example process of implementing an example neural network using two or more distinct neural layer circuits, according to some embodiments.

FIG. 10 is a flow diagram of a method of implementing a neural network based on a neural layer circuit corresponding to a single layer of the neural network, according to some embodiments.

Reference will now be made to embodiments, examples of which are illustrated in the accompanying drawings. In the following description, numerous specific details are set forth in order to provide a thorough understanding of the present invention. However, it will be apparent to one of ordinary skill in the art that the present invention may be practiced without requiring these specific details.

### DESCRIPTION OF EMBODIMENTS

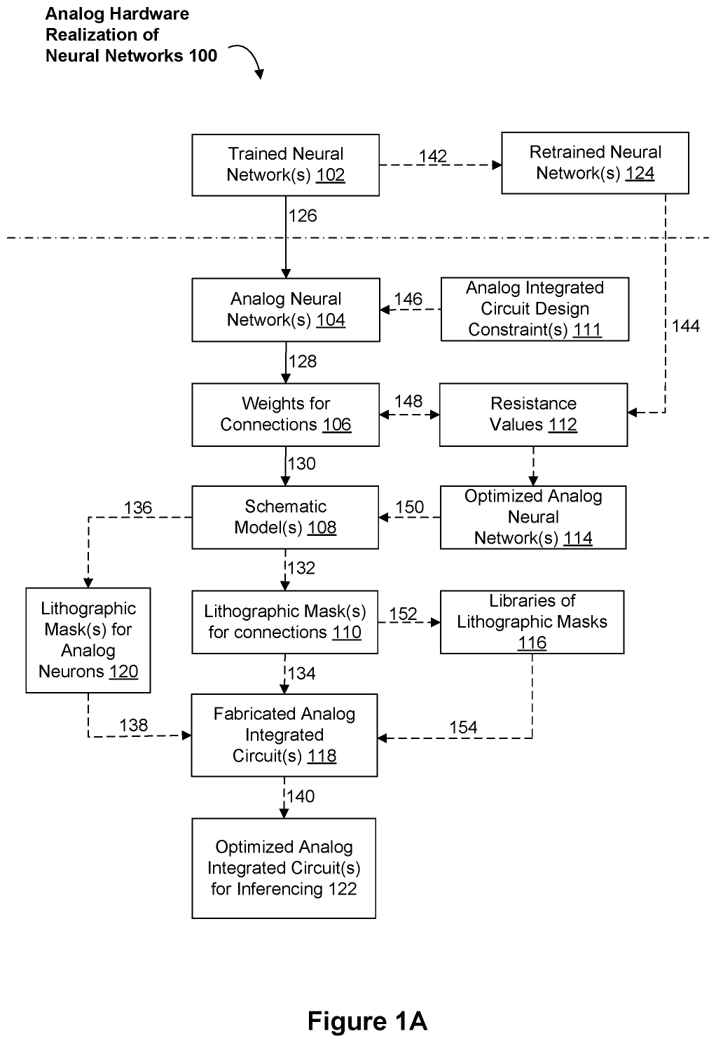

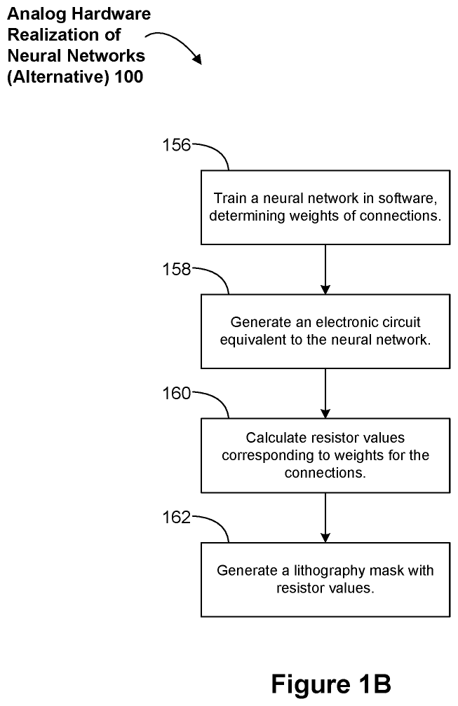

FIG. 1A is a block diagram of a system 100 for hardware realization of trained neural networks using analog components, according to some embodiments. The system includes transforming (126) trained neural networks 102 to analog neural networks 104. In some embodiments, analog integrated circuit constraints 111 constrain (146) the transformation (126) to generate the analog neural networks 104. Subsequently, the system derives (calculates or generates) weights 106 for the analog neural networks 104 by a process that is sometimes called weight quantization (128). In some embodiments, the analog neural network includes a plurality of analog neurons, each analog neuron represented by an analog component, such as an operational amplifier, and each analog neuron is connected to other analog neurons via connections. In some embodiments, the connections are represented using resistors that reduce the current flow between two analog neurons. In some embodiments, the system transforms (148) the weights 106 to resistance values 112 for the connections. The system subsequently generates (130) one or more schematic models 108 for implementing the analog neural networks 104 based on the weights 106. In some embodiments, the system optimizes resistance values 112 (or the weights 106) to form optimized analog neural networks 114, which are further used to generate (150) the schematic models 108. In some embodiments, the system generates (132) lithographic masks 110 for the connections and/or generates (136) lithographic masks 120 for the analog neurons. In some embodiments, the system fabricates (134 and/or 138) analog integrated circuits 118 that implement the analog neural networks 104. In some embodiments, the system generates (152) libraries of lithographic masks 116 based on the lithographic masks 110 for connections and/or lithographic masks 120 for analog neurons. In some embodiments, the system uses (154) the libraries of lithographic masks 116 to fabricate the analog integrated circuits 118. In some embodiments, when the trained neural networks 102 are retrained (142) to form update neural networks 124, the system regenerates (or recalculates) (144) the resistance values 112 (and/or the weights 106), the schematic model 108, and/or the lithographic masks 110 for connections. In some embodiments, the system reuses the lithographic masks 120 for the analog neurons. In other words, in some embodiments, only the weights 106 (or the resistance values 112 corresponding to the changed weights), and/or the lithographic masks 110 for the connections are regenerated. Since only the connections, the weights, the schematic model, and/or the corresponding lithographic masks for the connections are regenerated, as indicated by the dashed line, the process for (or the path to) fabricating analog integrated circuits for the retrained neural networks is substantially simplified, and the time to market for re-spinning hardware for neural networks is reduced, when compared to conventional techniques for hardware realization of neural networks. In some embodiments, an optimization pass (140) constructs optimized analog integrated circuits (122) for inferencing.

FIG. 1B is a block diagram of an alternative representation of the system 100 for hardware realization of trained neural networks using analog components, according to some embodiments. The system includes training (156) neural networks in software, determining weights of connections, generating (158) electronic circuit equivalent to the neural network, calculating (160) resistor values corresponding to weights of each connection, and subsequently generating (162) a lithography mask with resistor values.

The techniques described herein can be used to design and/or manufacture an analog neuromorphic integrated circuit that is mathematically equivalent to a trained neural network (either feed-forward or recurrent neural networks). According to some embodiments, the process begins with a trained neural network that is first converted into a transformed network comprised of standard elements. Operation of the transformed network is simulated using software with known models representing the standard elements. The software simulation is used to determine the individual resistance values for each of the resistors in the transformed network. Lithography masks are laid out based on the arrangement of the standard elements in the transformed network. Each of the standard elements are laid out in the masks using an existing library of circuits corresponding to the standard elements to simplify and speed up the process. In some embodiments, the resistors are laid out in one or more masks separate from the masks including the other elements (e.g., operational amplifiers) in the transformed network. In this manner, if the neural network is retrained, only the masks containing the resistors, or other types of fixed-resistance elements, representing the new weights in the retrained neural network need to be regenerated, which simplifies and speeds up the process. The lithography masks are then sent to a fab for manufacturing the analog neuromorphic integrated circuit.

In some embodiments, components of the system 100 described above are implemented in one or more computing devices or server systems as computing modules.

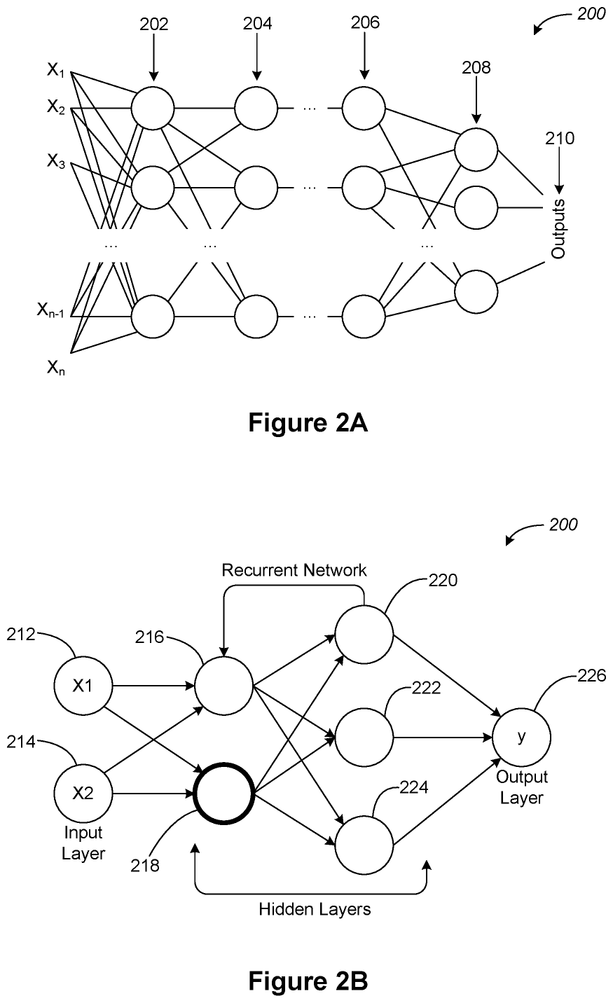

FIGS. 2A, 2B, and 2C show examples of trained neural networks 200 that are input to the system 100 and transformed into mathematically equivalent analog networks, according to some embodiments. FIG. 2A shows an example neural network 200 (sometimes called an artificial neural network) that is composed of artificial neurons that receive input, combine the input using an activation function, and produce one or more outputs. The input includes data, such as images, sensor data, and documents. Typically, each neural network performs a specific task, such as object recognition. The networks include connections between the neurons, each connection providing the output of a neuron as an input to another neuron. After training, each connection is assigned a corresponding weight. As shown in FIG. 2A, the neurons are typically organized into multiple layers, with each layer of neurons connected only to the immediately preceding and following layer of neurons. An input layer of neurons 202 receives external input (e.g., the input X₁, X₂, . . . , Xₙ). The input layer 202 is followed by one or more hidden layers of neurons (e.g., the layers 204 and 206), which is followed by an output layer 208 that produces outputs 210. Various types of connection patterns connect neurons of consecutive layers, such as a fully-connected pattern that connects every neuron in one layer to all the neurons of the next layer, or a pooling pattern that connects output of a group of neurons in one layer to a single neuron in the next layer. In contrast to the neural network shown in FIG. 2A that is sometimes called a feedforward network, the neural network shown in FIG. 2B includes one or more connections from neurons in one layer to either other neurons in the same layer or neurons in a preceding layer. The example shown in FIG. 2B is an example of a recurrent neural network and includes two input neurons 212 (that accepts an input X1) and 214 (that accepts an input X2) in an input layer followed by two hidden layers. The first hidden layer includes neurons 216 and 218, which are fully connected with neurons in the input layer, and the neurons 220, 222, and 224 in the second hidden layer. The output of the neuron 220 in the second hidden layer is connected to the neuron 216 in the first hidden layer, providing a feedback loop. The hidden layer including the neurons 220, 222, and 224 provides input to a neuron 226 in the output layer that produces an output y.

FIG. 2C shows an example of a convolutional neural network (CNN), according to some embodiments. In contrast to the neural networks shown in FIGS. 2A and 2B, the example shown in FIG. 2C includes different types of neural network layers, which includes a first stage of layers for feature learning, and a second stage of layers for classification tasks, such as object recognition. The feature learning stage includes a convolution and Rectified Linear Unit (ReLU) layer 230, followed by a pooling layer 232, which is followed by another convolution and ReLU layer 234, which is in turn followed by another pooling layer 236. The first layer 230 extracts features from an input 228 (e.g., an input image or portions thereof), and performs a convolution operation on its input, and one or more non-linear operations (e.g., ReLU, tanh, or sigmoid). A pooling layer, such as the layer 232, reduces the number of parameters when the inputs are large. The output of the pooling layer 236 is flattened by the layer 238 and input into a fully connected neural network with one or more layers (e.g., the layers 240 and 242). The output of the fully-connected neural network is input to a softmax layer 244 to classify the output of the layer 242 of the fully-connected network to produce one of many different outputs 246 (e.g., object class or type of the input image 228).

Some embodiments store the layout or the organization of the input neural networks including the number of neurons in each layer, the total number of neurons, operations, or activation functions of each neuron, and/or the connections between the neurons, in the memory 214, as the neural network topology.

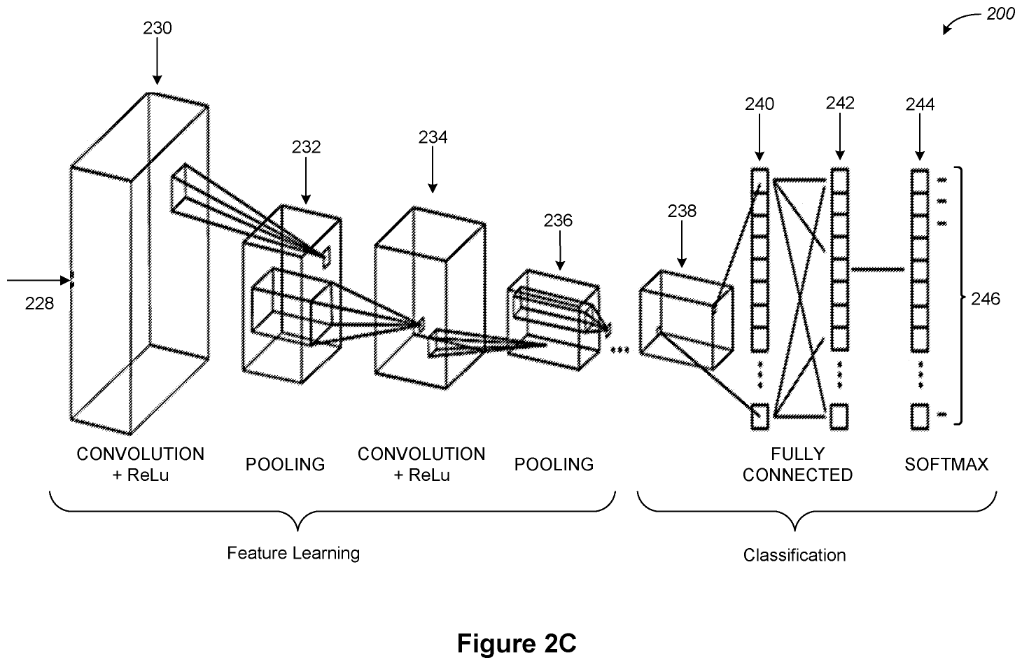

FIG. 3 shows an example of a mathematical model 300 for a neuron, according to some embodiments. The mathematical model includes incoming signals 302 multiplied by synaptic weights 304 and summed by a unit summation 306. The result of the unit summation 306 is input to a nonlinear conversion unit 308 to produce an output signal 310, according to some embodiments.

In some embodiments, the example computations described herein are performed by a weight matrix computation or weight quantization module (e.g., using a resistance calculation module), which computes the weights for connections of the transformed neural networks, and/or corresponding resistance values for the weights.

This section describes an example process for quantizing resistor values corresponding to weights of a trained neural network, according to some embodiments. The example process substantially simplifies the process of manufacturing chips using analog hardware components for realizing neural networks. As described above, some embodiments use resistors to represent neural network weights and/or biases for operational amplifiers that represent analog neurons. The example process described here specifically reduces the complexity in lithographically fabricating sets of resistors for the chip. With the procedure of quantizing the resistor values, only select values of resistances are needed for chip manufacture. In this way, the example process simplifies the overall process of chip manufacture and enables automatic resistor lithographic mask manufacturing on demand.

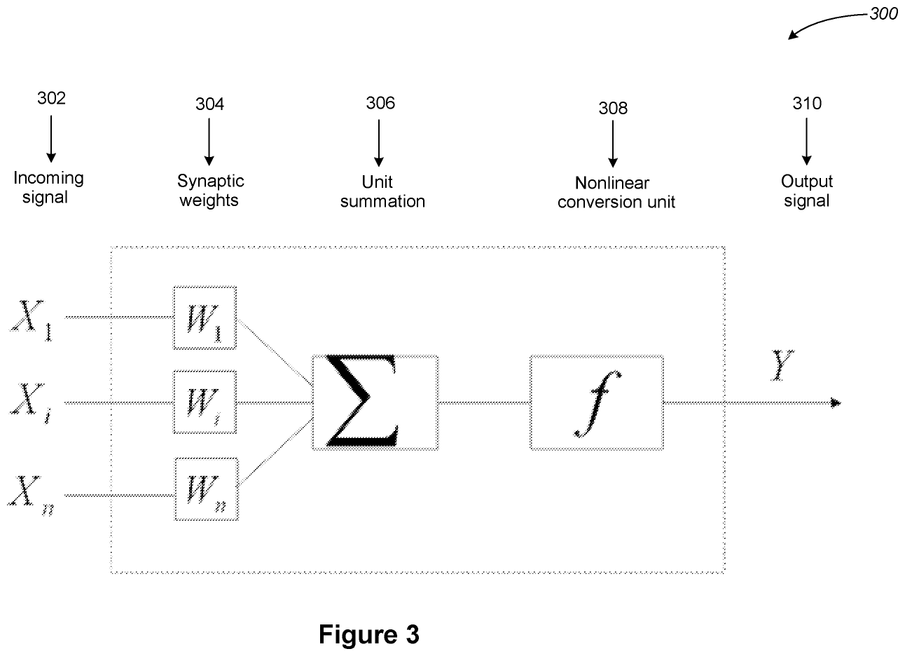

FIG. 4 is a schematic diagram of an example neuron circuit 400 for a neuron of a neural network used for resistor quantization, according to some embodiments. In some embodiments, the neuron circuit 400 is based on an operational amplifier 424 (e.g., AD824 series precision amplifier) that receives input signals U₁ and U₂ from a set of negative weight resistors 440RN (R1− 404, R2− 406, Rb− bias 416, Rn− 418, and R− 412) and a set of positive weight resistors 440RP (R1+ 408, R2+ 410, Rb+ bias 420, Rn+ 422, and R+ 414). The positive and negative weight resistors 440RP and 440RN are collectively called weight resistors 440. The positive weight resistors 440RP are coupled to a positive input 424P of the operational amplifier 424, and the negative weight resistors 440RN are coupled to a negative input 424N of the operational amplifier 424. The weight resistors 440 form a feedback network for the operational amplifier 424, allowing the operational amplifier 424 to implement a weighted summation operation on the input signals U₁ and U₂. The positive weighting resistors 440RP correspond to positive weights of the neuron corresponding to the neuron circuit 400, and the negative weighting resistors 440RN correspond to negative weights of the neuron corresponding to the neuron circuit 400. In some embodiments, the operational amplifier 424 is configured to combine the input signal U₁ and U₂ to facilitate normal circuit operation (e.g., linearly) and the output signal Uₒᵤₜ is output in a nominal voltage range between two power supplies of operational amplifier 424. In some embodiments, the operational amplifier 424 accomplishes ReLU transformation of the output signal Uₒᵤₜ at its output cascade.

Stated another way, in some embodiments, a neural network includes a plurality of layers, each of which includes a plurality of neurons. The neural network is implemented using an analog circuit including a plurality of resistors 440 and a plurality of amplifiers 424, and each neuron is implemented using at least a subset of resistors (e.g., positive weighting resistors 440RP and negative weighting resistors 440RN) and one or more amplifiers (e.g., amplifier 424). The neuron circuit 400 includes a combination circuit including an operational amplifier 424, a subset of resistors 440, two or more input interfaces, and an output interface. The combination circuit is configured to obtain two or more input signals (e.g., U₁ and U₂) at the two or more input interfaces, combine the two or more input signals (e.g., in a substantially linear manner), and generate an output Uₒᵤₜ. Broadly, the two or more input signals includes a number N of signals, and is linearly combined to generate the output Uₒᵤₜ as follows:

$${U}_{out} = {\sum }_{i = 1}^{N} ( \frac{{R}^{+}}{{R}_{i}^{+}} - \frac{{R}^{-}}{{R}_{i}^{-}} ) {U}_{i} . \qquad ( 1 )$$

For each input signal Uᵢ, a corresponding weight wᵢ is determined based on resistance of the subset of resistors 440 as follows:

$${w}_{i} = \frac{{R}^{+}}{{R}_{i}^{+}} - \frac{{R}^{-}}{{R}_{i}^{-}} . \qquad ( 2 )$$

For example, referring to FIG. 4, the neuron model 400 receives two input signals U₁ and U₂, and linearly combines the input signals U₁ and U₂ to generate an output Uₒᵤₜ. Weights applied to combine the input signals U₁ and U₂ are determined based on resistances of the resistors 400RP and 400RN used in the neuron circuit 400. The output Uₒᵤₜ and the weights wᵢ and w₂ are determined as follows:

$${U}_{out} = {w}_{1} {U}_{1} + {w}_{2} {U}_{2} . \qquad ( 3 )$$

For each input signal Uᵢ, a corresponding weight wᵢ is determined as follows:

$${w}_{1} = \frac{{R}^{+}}{{R}_{1}^{+}} - \frac{{R}^{-}}{{R}_{1}^{-}} and {w}_{2} = \frac{{R}^{+}}{{R}_{2}^{+}} - \frac{{R}^{-}}{{R}_{2}^{-}} . \qquad ( 4 )$$

In some embodiments, the following optimization procedure is applied to quantize resistance values of each resistance and minimize an error of the output Uₒᵤₜ:
1. Obtain a set of connection weights and biases {w₁, . . . , wₙ, b};
2. Obtain possible minimum and maximum resistor values {Rₘᵢₙ, Rₘₐₓ}, which are determined based on the technology used for manufacturing;
3. Assume that each resistor has r_err relative tolerance value;
4. Select a set of resistor values {R₁, . . . , Rₙ} of given length N within the defined [Rₘᵢₙ; Rₘₐₓ], based on {w₁, . . . , wₙ, b} values, where an example search algorithm is provided below to find sub-optimal {R₁, . . . , Rₙ} set based on particular optimality criteria; and
5. Apply another algorithm to choose {Rₙ, Rₚ, Rₙᵢ, Rₚᵢ} for a network given that {R₁ . . . Rₙ} is determined.

Some embodiments use TaN or Tellurium high resistivity materials. In some embodiments, the minimum value Rₘᵢₙ of resistor 440 is determined by minimum square that can be formed lithographically. The maximum value Rₘₐₓ is determined by length, allowable for resistors (e.g., resistors made from TaN or Tellurium) to fit to the desired area, which is in turn determined by the area of an operational amplifier square on lithographic mask. In some embodiments, the area of arrays of resistors 440RN and 440PR is formed in back end of line (BEOL), which allows the arrays of resistors are stacked, and is smaller in size than the area of the operational amplifier 424 formed in front end of line (FEOL).

Some embodiments use an iterative approach for resistor set search. Some embodiments select an initial (random or uniform) set {R1, . . . , Rn} within the defined range. Some embodiments select one of the elements of the resistor set as a R−=R+ value. Some embodiments alter each resistor within the set by a current learning rate value until such alterations produce ‘better’ set (according to a value function). This process is repeated for all resistors within the set and with several different learning rate values, until no further improvement is possible.

In some embodiments, a value function of a resistor set is defined. Specifically, possible weight options are calculated for each weight wᵢ according to equation (2). Expected error value for each weight option is estimated based on potential resistor relative error r_err determined by IC manufacturing technology. Weight options list is limited or restricted to [−wlim; wlim] range. Some values, which have expected error beyond a high threshold (e.g., 10 times r_err), are eliminated. The value function is calculated as a square mean of distance between two neighboring weight options. In an example, the weight options are distributed uniformly within [−wlim; wlim] range, and the value function is minimal.

In an example, the required weight range [−wlim; wlim] for a neural network is set to [−5, 5], and the other parameters include N=20, r_err=0.1%, rmin=100 KΩ, rmax=5 MΩ. Here, rmin and rmax are minimum and maximum values for resistances, respectively.

In one instance, the following resistor set of length 20 was obtained for abovementioned parameters: [0.300, 0.461, 0.519, 0.566, 0.648, 0.655, 0.689, 0.996, 1.006, 1.048, 1.186, 1.222, 1.261, 1.435, 1.488, 1.524, 1.584, 1.763, 1.896, 2.02]MΩ. Resistances of both resistors R− and R+ are equal to 1.763 MΩ.

Some embodiments determine Rn and Rp using an iterative algorithm such as the algorithm described above. Some embodiments set Rp=Rn (the tasks to determine Rn and Rp are symmetrical—the two quantities typically converge to a similar value). Then for each weight wᵢ, some embodiments select a pair of resistances {Rni, Rpi} that minimizes the estimated weight error value:

$${w}_{err} = ( \frac{{R}^{+}}{{R}_{i}^{+}} + \frac{{R}^{-}}{{R}_{i}^{-}} ) \cdot {r}_{err} + \vert {w}_{i} - \frac{{R}^{+}}{{R}_{i}^{+}} + \frac{{R}^{-}}{{R}_{i}^{-}} \vert \qquad ( 5 )$$

Some embodiments subsequently use the {Rni; Rpi; Rn; Rp} values set to implement neural network schematics. In one instance, the schematics produced mean square output error (sometimes called S mean square output error, described above) of 11 mV and max error of 33 mV over a set of 10,000 uniformly distributed input data samples, according to some embodiments. In one instance, S model was analyzed along with digital-to-analog converters (DAC), analog-to-digital converters (ADC), with 256 levels as a separate model. The S model produces 14 mV mean square output error and 49 mV max output error on the same data set, according to some embodiments. DAC and ADC have levels because they convert analog value to bit value and vice-versa. 8 bits of digital value is equal to 256 levels. Precision cannot be better than 1/256 for 8-bit ADC.

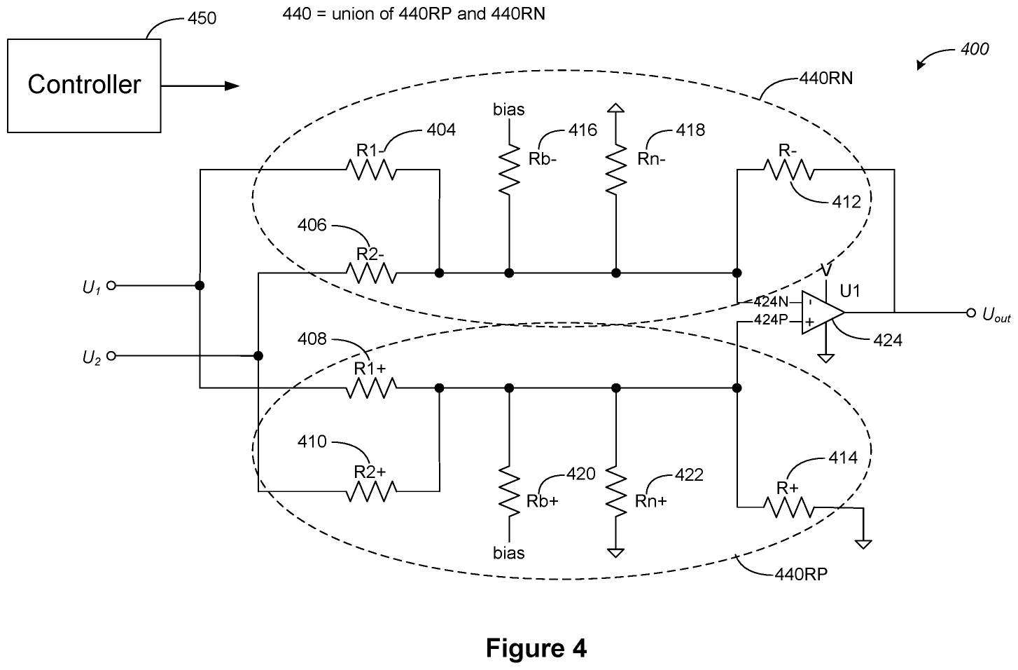

Some embodiments calculate the resistance values for analog IC chips, when the weights of connections are known, based on Kirchhoff's circuit laws and basic principles of operational amplifiers (described below in reference to FIG. 5), using Mathcad or any other similar software. In some embodiments, operational amplifiers are used both for amplification of signal and for transformation according to the activation functions (e.g., ReLU, sigmoid, Tangent hyperbolic, or linear mathematical equations),

Some embodiments manufacture resistors in a lithography layer where resistors are formed as cylindrical holes in the SiO₂ matrix, and the resistance value is set by the diameter of hole. Some embodiments use amorphous TaN, TiN of CrN or Tellurium as the highly resistive material to make high density resistor arrays. Some ratios of Ta to N Ti to N and Cr to N provide high resistance for making ultra-dense high resistivity elements arrays. For example, for TaN, Ta₅N₆, Ta₃N₅, the higher the N ratio to Ta, the higher is the resistivity. Some embodiments use Ti2N, TiN, CrN, or Cr₅N, and determine the ratios accordingly. TaN deposition is a standard procedure used in chip manufacturing and is available at all major Foundries.

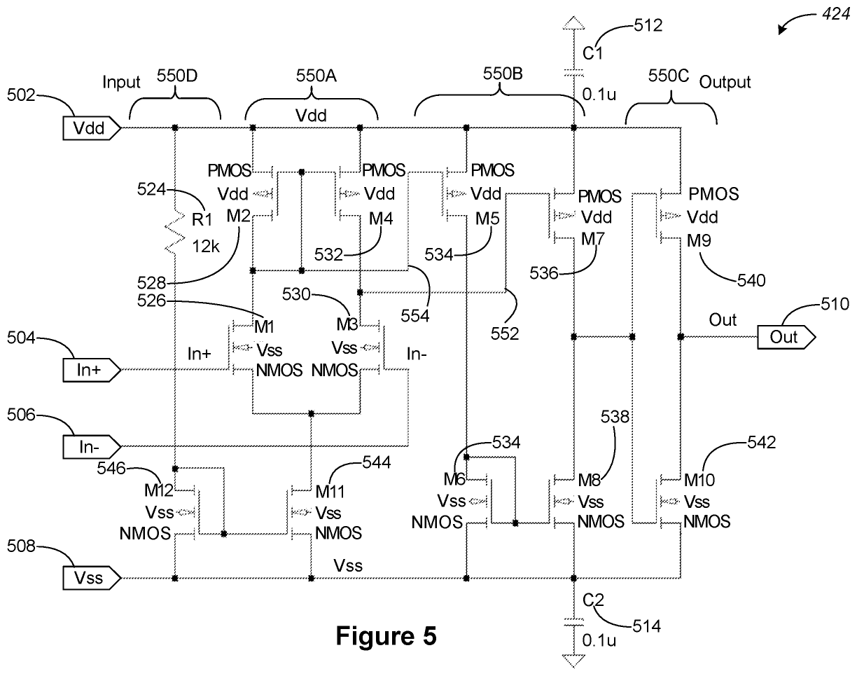

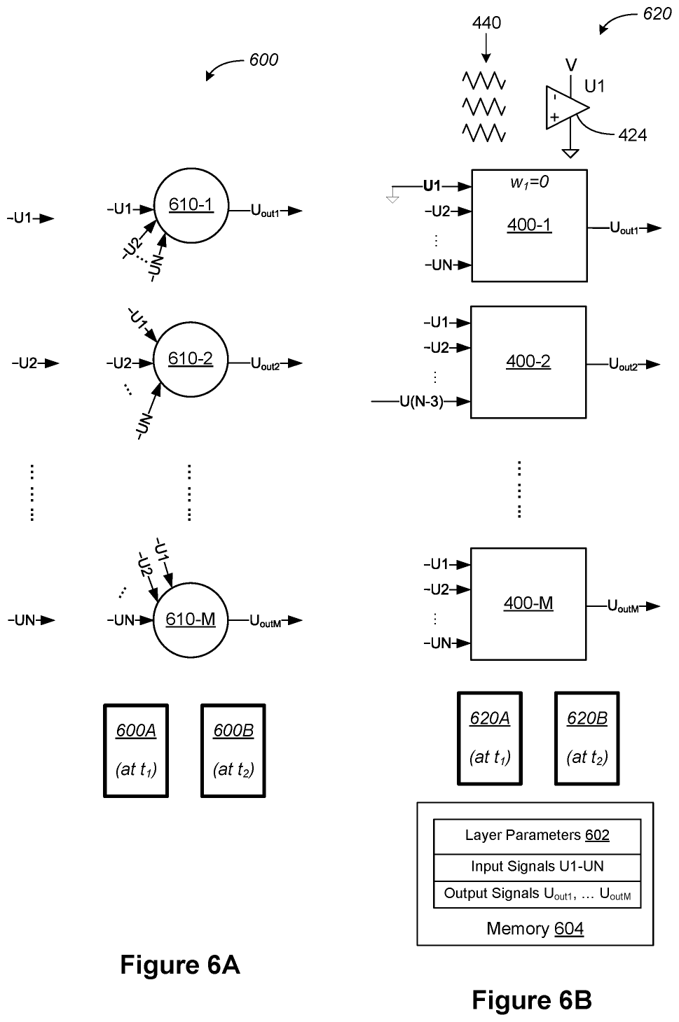

In some embodiments, a subset of weight resistors 440 have variable resistance. For example, the subset of weight resistors 440 includes resistors R+ 414, R2+ 410, and R1− 404. Further, in some embodiments, a neural network includes a plurality of neural layers, and the subset of weight resistors 440 having variable resistance are applied to implement neurons in a subset of neural layers that is directly coupled to an output of the neural network. For example, the neural network has more than 10 layers, and weight resistors 440 having variable resistance is used to implement one or more neurons in the last one or two layers of the neural network. More details on resistor-based weight adjustment in the neuron circuit 400 are explained below with reference to FIGS. 6A-10.

FIG. 5 is a schematic diagram of an example operational amplifier 424, according to some embodiments. In some embodiments, the operational amplifier 424 is applied to form the neuron circuit 400 shown in FIG. 4. The operational amplifier 424 is coupled to a feedback network including a set of negative weight resistors 440RN and a set of positive weight resistors 440RP, forming the neuron circuit 400 configured to combine a plurality of input signals Uᵢ (e.g., U₁ and U₂) and generate an output Uₒᵤₜ. The operational amplifier 424 includes a two-stage amplifier having N-type different inputs. The differential inputs include a positive input 504 (In+) and a negative input 506 (In−). The operational amplifier 424 is powered by two power supplies, e.g., a positive supply voltage 502 (Vdd), a negative supply voltage 508 (Vss) or a ground GND.

The operational amplifier 424 includes a plurality of complementary metal-oxide semiconductor (CMOS) transistors (e.g., having both P-type transistors and N-type transistors). In some embodiments, performance parameters of each CMOS transistor (e.g., drain current I_{D}) are determined by a ratio of geometric dimensions: W (a channel width) to L (a channel length) of the respective CMOS transistor. The operational amplifiers 424 includes one or more of a differential amplifier stage 550A, a second amplifier stage 550B, an output stage 550C, and a biasing stage 550D. Each circuit stage of the operational amplifier 424 is formed based on a subset of the CMOS transistors.

A biasing stage 550D includes NMOS transistor M12 546 and resistor R1 521 (with an example resistance value of 12 kΩ), and is configured to generate a reference current. A current mirror is formed based on NMOS transistors M11 544 and M12 546, and provides an offset current to the differential pair (M1 526 and M3 530) based on the reference current of the biasing stage 550D. The differential amplifier stage 550A (differential pair) includes NMOS transistors M1 526 and M3 530. Transistors M1, M3 are amplifying, and PMOS transistors M2 528 and M4 532 play a role of active current load. A first amplified signal 552 is outputted from a drain of transistor M3 530, and provided to drive a gate of PMOS transistor M7 536 of a second amplifier stage 500B. A second amplified signal 554 is outputted from a drain of transistor M1 526, and provided to drive a gate of PMOS transistor M5 (inverter) 534, which is an active load on the NMOS transistor M6 534. A current flowing through the transistor M5 534 is mirrored to the NMOS transistor M8 538. Transistor M7 536 is included with a common source for a positive half-wave signal. The M8 transistor 538 is enabled by a common source circuit for a negative half-wave signal. The output stage 550C of the operational amplifier 424 includes P-type transistor M9 540 and N-type transistor M10 542, and is configured to increase an overall load capacity of the operational amplifier 424. In some embodiments, a plurality of capacitors (e.g., C1 512 and C2 514) is coupled to the power supplies 502 and 508, and configured to reduce noise coupled into the power supplies and stabilize the power supplies 502 and 508 for the operational amplifier 424.

In some embodiments, an electronic device includes a plurality of resistors 440RN and 440RP and one or more amplifiers 424 coupled to the plurality of resistors 440RN and 440RP. In some embodiments, the one or more amplifiers 424 and the plurality of resistors 440RN and 440RP are formed on a substrate of an integrated circuit. In some embodiments, the integrated circuit implementing the neural network is packaged and used in an electronic device as a whole. Conversely, in some embodiments, at least one of the one or more amplifiers 424 is formed on an integrated circuit, and packaged and integrated on a printed circuit board (PCB) with remaining resistors or amplifiers of the same neural network. In some embodiments, the plurality of resistors 440RN and 440RP and the one or more amplifiers 424 of the same neural network are formed on two or more separate integrated circuit substrates, which are packaged separately and integrated on the same PCB to form the electronic device. Two or more packages of the electronic device are configured to communicate signals with each other and implement the neural network collaboratively.

Analog circuits that model trained neural networks and manufactured according to the techniques described herein, can provide improved performance per watt advantages, can be useful in implementing hardware solutions in edge environments, and can tackle a variety of applications, such as drone navigation and autonomous cars. The cost advantages provided by the proposed manufacturing methods and/or analog network architectures are even more pronounced with larger neural networks. Also, analog hardware embodiments of neural networks provide improved parallelism and neuromorphism. Moreover, neuromorphic analog components are not sensitive to noise and temperature changes, when compared to digital counterparts.

Chips manufactured according to the techniques described herein provide order of magnitude improvements over conventional systems in size, power, and performance, and are ideal for edge environments, including for retraining purposes. Such analog neuromorphic chips can be used to implement edge computing applications or in Internet-of-Things (IoT) environments. Due to the analog hardware, initial processing (e.g., formation of descriptors for image recognition), that can consume over 80-90% of power, can be moved on chip, thereby decreasing energy consumption and network load that can open new markets for applications.

Various edge applications can benefit from use of such analog hardware. For example, for video processing, the techniques described herein can be used to include direct connection to CMOS sensor without digital interface. Various other video processing applications include road sign recognition for automobiles, camera-based true depth and/or simultaneous localization and mapping for robots, room access control without server connection, and always-on solutions for security and healthcare. Such chips can be used for data processing from radars and lidars, and for low-level data fusion. Such techniques can be used to implement battery management features for large battery packs, sound/voice processing without connection to data centers, voice recognition on mobile devices, wake up speech instructions for IoT sensors, translators that translate one language to another, large sensors arrays of IoT with low signal intensity, and/or configurable process control with hundreds of sensors.

Neuromorphic analog chips can be mass produced after standard software-based neural network simulations/training, according to some embodiments. A client's neural network can be easily ported, regardless of the structure of the neural network, with customized chip design and production. Moreover, a library of ready to make on-chip solutions (network emulators) are provided, according to some embodiments. Such solutions require only training, one lithographic mask change, following which chips can be mass produced. For example, during chip production, only part of the lithography masks need to be changed.

FIG. 6A is a structural diagram of an example neural layer 600 of a neural network 200, in accordance with some embodiments, and FIG. 6B is a block diagram of an example neural layer circuit 620 that implements the neural layer 600 in FIG. 6A, in accordance with some embodiments. The neural layer 600 has a plurality of neurons 610 (e.g., M neurons), and each neuron 610 is configured to receive a respective set of inputs and generate an output from the respective set of inputs. For example, the neural layer 600 receives a plurality of inputs (e.g., U1, U2, . . . , and UN) and generates a plurality of outputs (e.g., Uₒᵤₜ₁, Uₒᵤₜ₂, . . . , and U_{outM}). In some embodiments, in accordance with a determination that the neural network 200 is fully connected, each neuron 610 receives all of the plurality of inputs U1-UN and generates the output according to the math model 300. Specifically, a first neuron 610-1 generates its output Uₒᵤₜ₁ based on a first weighted combination of all of the inputs U1-UN, and a second neural 610-2 generates its output Uₒᵤₜ₂ based on a second combination of all of the inputs U1-UN. An M-th neuron 610-M generates its output U_{outN} based on an M-th weighted combination of all of the inputs U1-UN.

Alternatively, in some embodiments, in accordance with a determination that the neural network 200 is not fully connected, each neuron 610 receives a respective subset of the plurality of inputs U1-UN and generates the output according to the math model 300 as well. Specifically, the first neuron 610-1 generates its output Uₒᵤₜ₁ based on a first weighted combination of a first subset of inputs, and the second neural 610-2 generates its output Uₒᵤₜ₂ based on a second combination of a second subset of inputs. The M-th neuron 610-M generates its output U_{outM} based on an N-th weighted combination of an M-th subset of inputs. For each neuron 610, a remainder of the respective subset of inputs is skipped (e.g., not used, equal to zero). From a different perspective, each neuron 610 receives all of the plurality of inputs U1-UN and generates the output based on a respective weighted combination of all inputs U1-UN according to the math model 300. The respective subset of the plurality of inputs U1-UN corresponds to weights that are not equal to zero, while the remainder of the respective subset of inputs corresponds to weights that are equal to zero.

Referring to FIG. 6B, in some embodiments, each of the neurons 610 is implemented using a respective neuron circuit 400 including an amplifier 424 and a plurality of weight resistors 440 (FIG. 4). Each of the neuron circuits 400 is configured to generate a respective output from at least a subset of the inputs U1-UN. The plurality of weight resistors 440 further include a plurality of positive weight resistors 440RP and a plurality of negative weight resistors 440RN, and are electrically coupled to the amplifier 424. The plurality of weight resistors 440 are configured to provide resistive feedback to the amplifier 424 to enable the respective neuron circuit 400. Each neuron 610 has a plurality of weights corresponding to its inputs. Each neuron circuit 400 has a set of layer parameters 602 including resistance values of the plurality of weight resistors 440, which are determined by the plurality of weights of a respective neuron 610. The layer parameters 602 of each neural layer circuit 620 are stored in memory 604 and extracted from the memory 604 to configure resistors 440 and amplifiers 424 of the neuron layer circuit 620 to realize the corresponding neural layer 600.

In some embodiments, in accordance with a determination that the neural network 200 is fully connected, each neuron circuit 400 receives all of the plurality of inputs U1-UN and generates the associated output via its respective weight resistors 440 and amplifier 424. Specifically, a first neuron circuit 400-1 generates its output Uₒᵤₜ₁ based on a first weighted combination of all of the inputs U1-UN, and a second neuron circuit 400-2 generates its output Uₒᵤₜ₂ based on a second combination of all of the inputs U1-UN. An M-th neuron circuit 400-M generates its output U_{outM} based on an M-th weighted combination of all of the inputs U1-UN.

Alternatively, in some embodiments, in accordance with a determination that the neural network 200 is not fully connected, each neuron circuit 610 receives a respective subset of the plurality of inputs U1-UN and generates the output via its respective weight resistors 440 and amplifier 424. For each neuron circuit 400-1, 400-2, . . . , or 400-M, a remainder of the respective subset of inputs is skipped (e.g., shorted to ground, equal to zero). From a different perspective, in some embodiments, each neuron circuit 610 receives all of the plurality of inputs U1-UN and generates the output based on a respective weighted combination of all inputs U1-UN. The respective subset of the plurality of inputs U1-UN corresponds to weights that are not equal to zero, while a remainder of the respective subset of inputs corresponds to weights that are equal to zero. For example, for the first neuron circuit 400-1, the input U1 is not used, and a first weight w₁ is equal to zero. The resistors R+ and R− have equal resistance, so are the resistors R1+ and R1−. Additionally and alternatively, in some embodiments, each neuron circuit 400 skips the remainder of the respective subset of inputs and sets the resistance values of the resistors 440 to make the corresponding weights equal to 0.

In some embodiments, the neural layer circuit 620 is configured to implement a first layer 600A and a second layer 600B at two distinct times t₁ and t₂, wherein the time t₂ is later than the time t₁. The first layer 600A has a first number M₁ of neurons 610 and a first number N₁ of inputs, and the second layer 600B has a second number M₂ of neurons 610 and a second number N₂ of inputs. For the layers 600A and 600B, their associated layer parameters 602 include the numbers M₁, N₁, M₂, and N₂. Further, in some embodiments, the first number M₁ is distinct from (e.g., greater than, less than) the second number M₂. The first layer 600A and 600B are implemented using different subsets of the neuron circuits 400-1 to 400-M including different numbers of circuits 400, and the different subsets of the neuron circuits optionally share or do not share any neuron circuit 400. Alternatively, in some embodiments, the first number M₁ is equal to the second number M₂. The first layer 600A and 600B are optionally implemented using the same subset of the neuron circuits 400-1 to 400-M or using different subsets of the neuron circuits 400-1 to 400-M. Each of the numbers M₁ and M₂ is equal to or smaller than a total number of neuron circuit 400 (e.g., M) included in the neural layer circuit 620.

In some embodiments, the first number N₁ is distinct from (e.g., greater than, less than) the second number N₂. Alternatively, in some embodiments, the first number N₁ is equal to the second number N₂. Each neuron circuit 400 skips a remainder of the respective subset of inputs that are in use and/or sets the resistance values of the resistors 440 to make the weights corresponding to the remainder of the respective subset of inputs equal to 0. Each of the numbers N₁ and N₂ is equal to or smaller than a total number of inputs (e.g., N) included in the neural layer circuit 620. In some embodiments, all of the neuron circuits 400 of the neural layer circuit 620 are configured to receive and combine up to the same total number of inputs. Alternatively, in some embodiments, at least one of the neuron circuits 400 (e.g., 400-2) of the neural layer circuit 620 are configured to receive and combine a number (e.g., N−3) of inputs that is distinct from the total number (e.g., N) of inputs.

In some embodiments, the neural layer circuit 620 is applied to implement each of a plurality of layers 600 of a neural network 200 sequentially using a collection of resistors 440 and a collection of amplifiers 424 of the neuron circuits 400 (e.g., 400-1 to 400-M). For example, at the first time t₁, a plurality of layer parameters 602 are extracted from memory and corresponds to a plurality of weights of the respective layer 600A. In accordance with the plurality of layer parameters 602 (e.g., M₁, N₁, M₂, N₂, weight resistances), a plurality of resistors 620 are selected from the collection of resistors 440, and a plurality of amplifiers from the collection of amplifiers 424. The plurality of amplifiers are electrically coupled to the plurality of resistors. The plurality of selected resistors form a set of input resistors 440 (e.g., resistors 404-410 in FIG. 4), and the set of input resistors 440 are electrically coupled to the plurality of amplifiers 424 to form a neural layer circuit 620, which obtains a plurality of input signals (e.g., U1-UN) via the plurality of resistors and generates a plurality of output signals (e.g., Uₒᵤₜ₁, Uₒᵤₜ₂, . . . , U_{outM}) from the plurality of input signals.

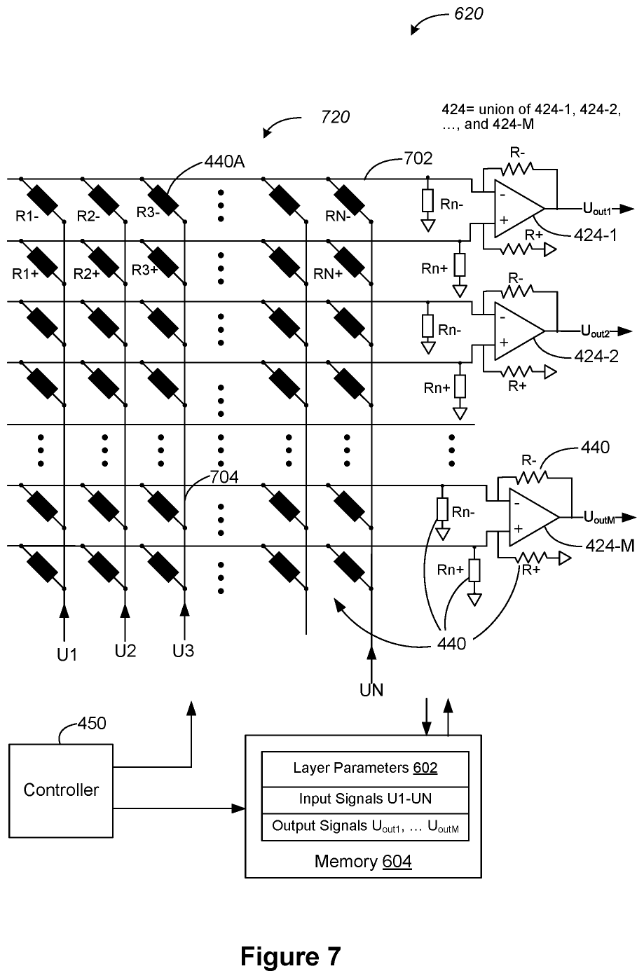

FIG. 7 is a schematic diagram of an example neural layer circuit 620 for implementing a neural layer 600 based on a crossbar array 720 of resistive elements, in accordance with some embodiments. A plurality of amplifiers 424 (e.g., 424-1, 424-2, . . . 424-M) are coupled to a plurality of weight resistors 440 (e.g., resistive elements in the crossbar array 720, resistors R+, R−, Rn+, and Rn− coupled to each amplifier 424) to form the neural layer circuit 620. An example of the neural layer 600 that can be similarly implemented by the neural layer circuit 620 is any of neural layers 202-208 in FIG. 2A. In some embodiments, a subset of the plurality of weighted resistors 440 is selected from a crossbar array 720 of resistive elements having a plurality of word lines 702, a plurality of bit lines 704, and a plurality of resistive elements (e.g., R1+, R1−, R2+, R2−, . . . , RN+, and RN− coupled to a first amplifier 424-1). Each resistive element is located at a cross point of, and electrically coupled between, a respective word line 702 and a respective bit line 704.

In some embodiments, the neural layer circuit 620 corresponds to a plurality of layer parameters 602 including a number of inputs (N), a number of neurons (M), and resistance values of the pairs of weight resistors 440 corresponding to the amplifiers 424-1 to 424-M, e.g., weight resistors R1+ and R1−, R2+ and R2−, . . . , and RN+ and RN− corresponding to the first amplifier 424-1. Further, in some embodiments, the neural layer circuit 620 is further coupled to a controller 450 and memory 604. The memory 604 stores the plurality of layer parameters 602 of a plurality of layers 600 of a trained neural network 200. To realize a specific layer using the neural layer circuit 620, the controller 450 extracts the plurality of layer parameters 602 from the memory 604 and configures a collection of resistors 440 and a collection of amplifiers 424 based on the plurality of layer parameters 602.

In some embodiments, each amplifier 424 corresponds to a respective neuron 610 of the neural layer 600, and a weighted linear combination operation is implemented via the amplifier 424 and a feedback network that is formed by the plurality of weight resistors 440 and coupled to the respective amplifier 424. The plurality of weight resistors 440 correspond to a plurality of weights of the neural layer 600. For example, a first amplifier 424-1 corresponds to two rows of input resistors 440 formed by the crossbar array 720. The two rows of input resistors 440 include N pairs of weight resistors corresponding to the plurality of inputs U1-UN. For example, a first input U1 corresponds to, and is coupled to, a first pair of weight resistors R1+ and R1−, and the weight resistors R1+ and R1− are further coupled to a positive input and a negative input of the first amplifier 424-1.

In some embodiments, the neural layer circuit 620 uses a subset of the amplifiers 424 and associated weight resistors. A remainder of the amplifiers 424 is disabled while the neural layer circuit 620 is implemented. For example, in some situations, the amplifier 424-2 is disabled to skip a corresponding neuron of the neural layer 600. Alternatively, in some embodiments, all weights corresponding to the remainder of the amplifiers 424 that is not used are set to 0. In an example, resistors R+ and Rn+ are equal to R− and Rn−, respectively. Each pair of weight resistors coupled to the amplifier 424-2 are adjusted to have equal resistance values.

In some embodiments, the neural layer circuit 620 uses a subset of the plurality of inputs U1-UN, and a remainder of the plurality of inputs U1-UN, which is not in use, is grounded. Alternatively, in some embodiments, resistors R+ and Rn+ are equal to R− and Rn−, respectively. Each pair of weight resistors 449 coupled to the unused remainder of the plurality of inputs U1-UN are adjusted to have equal resistance values, such that the corresponding weight is equal to 0. Alternatively and additionally, in some embodiments, the remainder of the plurality of inputs U1-UN is grounded, and Each pair of weight resistors coupled thereto are adjusted to have equal resistance values. For example, the second input U2 is grounded, or resistance values of the resistors R2+ and R2− are set to be equal for each amplifier 424, thereby disabling the second input U2 for the neural layer circuit 620.

In some embodiments, a subset of the plurality of weight resistors 440 (e.g., resistive elements in the crossbar array 720, resistors R+, R−, Rn+, and Rn− coupled to each amplifier 424) is adjustable and has variable resistance. For example, the resistor R1− coupled to the first amplifier 424-1 has an adjustable resistance. In another example, each and every one resistive element in the crossbar array 720 has an adjustable resistance. In some situations, all of the plurality of weight resistors 440 have adjustable resistances. In some embodiments, the subset of the plurality of resistors includes a first resistor 440A (e.g., the resistor R3− coupled to the first amplifier 424-1) having a variable resistance. Further, in some embodiments, the first resistor 440A includes at least one photo resistor, which is configured to be exposed to a controllable source of light, and the variable resistance of the first resistor 440A depends on a brightness level of the controllable source of light. Additionally, in some embodiments, the photo resistor includes one or more of: cadmium sulfide (CdS), cadmium selenide (CdSe), lead sulfide (PbS) and indium antimonide (InSb), and titanium oxide (TiO₂). Specifically, in an example, the first resistor is configured to have a first resistance and a second resistance. In accordance with a determination that a weight of a first layer has a first value, the source of light is controlled to make the first resistor 440A provide the first resistance. In accordance with a determination that a weight of a second layer has a second value, the source of light is controlled to make the first resistor 440A provide the second resistance.

In some embodiments, referring to FIG. 7, a subset of the plurality of weighted resistors 440 (e.g., R1+, R1−, R2+, R2−, . . . , RN+, and RN− coupled to a first amplifier 424-1) forms a crossbar array 720 of resistive elements. Alternatively, in some embodiments, a subset of the plurality of resistors 440 are selected from a crossbar array of NOR flash memory cells having a plurality of word lines 702, a plurality of bit lines 704, and a plurality of NOR flash memory cells. Each NOR flash memory cell is located at a cross point of, and electrically coupled between, a respective word line and a respective bit line and configured to provide a respective NOR flash memory cell as a respective resistive element. Alternatively, in some embodiments, a subset of the plurality of resistors 440 are selected from a crossbar array of memristors having a plurality of word lines 702, a plurality of bit lines 704, and a plurality of memristors. Each memristor is located at a cross point of, and electrically coupled between, a respective word line and a respective bit line and configured to provide a respective one of the collection of resistors 440. Alternatively, in some embodiments, a subset of the plurality of resistors 440 are selected from a crossbar array of phase-change memory (PCM) memory cells having a plurality of word lines 702, a plurality of bit lines 704, and a plurality of PCM memory cells. Each PCM memory cell is located at a cross point of, and electrically coupled between, a respective word line and a respective bit line and configured to provide a respective one of the collection of resistors 440. Alternatively, in some embodiments, a subset of the plurality of resistors are selected from a crossbar array of magnetoresistive memory cells having a plurality of word lines 702, a plurality of bit lines 704, and a plurality of magnetoresistive memory cells. Each magnetoresistive memory cell is located at a cross point of, and electrically coupled between, a respective word line and a respective bit line and configured to provide a respective one of the collection of resistors 440.

In various embodiments of the application, the neural layer circuit 620 is applied to sequentially implement each of a plurality of layers 600 of a neural network 200 using a collection of resistors 440 and a collection of amplifiers 424. For each of the plurality of layers 600, a plurality of layer parameters 602 corresponding to a plurality of weights of the respective layer 600 are extracted from the memory 604. In accordance with the plurality of layer parameters 602, a controller 450 selects a plurality of resistors 440 from the collection of resistors 440 and a plurality of amplifiers from the collection of amplifiers 424. The plurality of amplifiers 424 are electrically coupled to the plurality of resistors 440. As explained above, All or a subset of the resistors 440 and amplifiers 424 are selected, e.g., based on the number of inputs (N) and the number of neurons (M) involved in the corresponding neural layer 600. In other words, not every row of resistors in the crossbar array 720 of resistors is selected. The selected resistors 440 forms a set of input resistors 440 (e.g., R1+, R1−, R2+, R2−), which are electrically coupled to the plurality of amplifiers 424 to form the neural layer circuit 620. The neural layer circuit 620 obtains a plurality of input signals (e.g., U1-UN) via the plurality of resistors Rin, and generates a plurality of output signals (e.g., Uₒᵤₜ₁-U_{outM}) from the plurality of input signals U1-UN.

In some embodiments, each of the input resistors 440 (e.g., R2−) has two terminals including a first terminal for receiving a respective input signal (e.g., U2) and a second terminal coupled to an input of a respective amplifier 424 (e.g., a negative input of the amplifier 424-1). Further, in some embodiments, each of the set of input resistors 440 has a respective resistance value that is defined by the plurality of layer parameters 602 to reach a predefined precision level (e.g., 8-bit).

In some embodiments, each of the plurality of resistors 440 has an input terminal and an alternative terminal. For each of the plurality of input signals, input terminals of a respective subset of the plurality of resistors 440 are electrically coupled to form a respective input interface for receiving the respective input signal. A weight of the respective input signal depends on resistance values of the respective subset of the plurality of resistors 440. Additionally, in some embodiments, the alternative terminal of each of the subset of the resistors electrically coupling to a respective input interface (e.g., a positive input or a negative input) of a respective amplifier 424. For example, input terminals of the first column of resistors 440 in FIG. 7 are coupled to form an input interface for receiving a first input signal U1. A weight of the first signal U1 is used to generate a first output signal Uₒᵤₜ₁ and depends on the input resistors R1− and R1+. The alternative terminals of the input resistors R1− and R1+ are coupled to the inputs of the first amplifier 424-1.

Stated another way, in some embodiments, each of the plurality of resistors has an input terminal and an alternative terminal. Each of the plurality of input signals U1-UN is electrically coupled to the input terminal of a respective one of a subset of the plurality of resistors 440 for receiving the respective input signal. A weight of each input signal depends partially on a resistance value of the respective one of the subset of the plurality of resistors 440. The alternative terminal of each of the subset of the plurality of resistors is coupled to an input interface of a respective amplifier 424. For example, the subset of the plurality of resistors 440 corresponds to the first row of input resistors R1−, R2−, R3, . . . , and RN−, and the alternative terminals of the first row of input resistors R1−, R2−, R3, . . . , and RN− are coupled to a negative input of the first amplifier 424-1.

Referring to FIG. 7, in some embodiments, the crossbar array 720 represents a crossbar array 720 of memory cells. Each resistive element represents an equivalent resistor of a respective memory cell. A method of processing a large neural network 200 on a programmable an analog memory crossbar is proposed. A neural network 200 is transformed into segments. Each segment includes a single layer 600 (also called a fragment), and is implemented sequentially using a programmable analog memory crossbar 720. In some embodiments, weights of a neural network segment (e.g., layer 600) are stored digitally (e.g., with a 8-bit precision level) and then uploaded into an analog 8-bit precision crossbar to set resistance value of each memory cell of the analog memory crossbar 720 with the 8-bit precision level. For example, the resistance value is set by an optocoupler or to a magnetoresistive random-access memory (MRAM) cell.

In some embodiments, fragmentation includes one or more of: (1) a plurality of scalar multiply-accumulate operations within a directed acyclic graph (DAG) of operations produced by a T-compiler transformation; (2) a plurality of fragments whereas a plurality of multiply-accumulate operations corresponds to a single fragment; (3) a plurality of MicroLEDs and photoresistors, and their values, within each fragment, where each multiplication coefficient of a scalar multiply-accumulate operator corresponds to a set of MicroLEDs and photoresistors according to fragmentation rules; and (4) a plurality of multibit MRAM cells organized into a crossbar array, where each multiplication coefficient of a scalar multiply-accumulate operator corresponds to a crossbar element according to fragmentation rules. Further, in some embodiments, fragmentation puts into a fragment any scalar multiply-accumulate operations, which are independent within a DAG of operations (i.e., in the DAG there does not exist any path between either of the two of chosen operations). For operations united into a fragment, fragmentation represents inputs of these operations as fragment (crossbar) inputs and outputs of these operations as fragment (crossbar) outputs. In some embodiments, fragmentation produces one or multiple crossbar units according to fragmentation rules. Each crossbar of analog memory cells is accompanied by means of applying analog input signals (i.e., Digital-to-analog converters), measuring and storing output signals (i.e., analog-to-digital converters and digital data registers, or short-term analog memory), and programming weight values (i.e., digital weight storage memory, LED drivers and microLEDs to apply light to an array of photoresistors).

An overall latency of a multilayer neural network 200 is equal to a sum of latencies of signal propagation through each of a plurality of layers 600 of the neural network 200. For example, MobileNet is split into 29 fragments, corresponding to 30 layers of the network, with each fragment consisting of 370000 weights and 3460 neurons. The crossbar is used to be able to implement any of each-to-each connection between fragment's inputs and outputs. The structure has excessive weights, and a physical implementation of a fragment hardware will have 3460 inputs, 3460 outputs, and 11971600 weights—crossbar connections. Conversely, such a complex neural network is implemented via fragmentation using a combination of a single crossbar array and a digital memory 604.

In some embodiments, splitting of a neural network into a set of fragments is accomplished as part of a neural network compiler software, which is implemented as explained above with reference to at least FIGS. 1A and 1B. A custom-designed compiler block is applied to split a neural network 200 into segments suitable for hardware implementation, taking into account at least one of: crossbars size, amounts of available inputs and outputs, available weight, and signal precision and allowing proper mapping of a fragmented neural network 20 into dedicated hardware. This hardware dedicated to the implementation of a fragmented neural network 200 is a mixed-signal circuit including one or more of: an analog memory crossbar 720, digital weight storage memory 604, and supportive circuitry responsible for analog memory programming, input signals application, and output signals measurement.

In some embodiments, weights of the whole neural network 200 are stored digitally and applied to analog memory fragment-by-fragment, enabling reuse of the same hardware crossbar for multiple neural network segments. Further, in some embodiments of optocoupler realization, digital weight values are applied to individual drivers that form control signals for the array of microLEDs. These microLEDS, in turn, control resistance values of corresponding photoresistors acting as weights in an analog NASP computational core. In case of multi-bit MRAM being used, digital weight values are fed into a MRAM writing circuit that rewrites values of MRAM memory cells in a crossbar before each calculation. Fragmentation is universal and allows calculation of a plurality of neural networks (e.g., a convolutional neural network (CNN) and a recurrent neural network (RNN), an autoencoder, and a perceptron). In fragmentation realized through a proprietary T-compiler, a number of neurons is adjustable for different layers 600, making fragmentation of neural networks into evenly sized fragments possible.

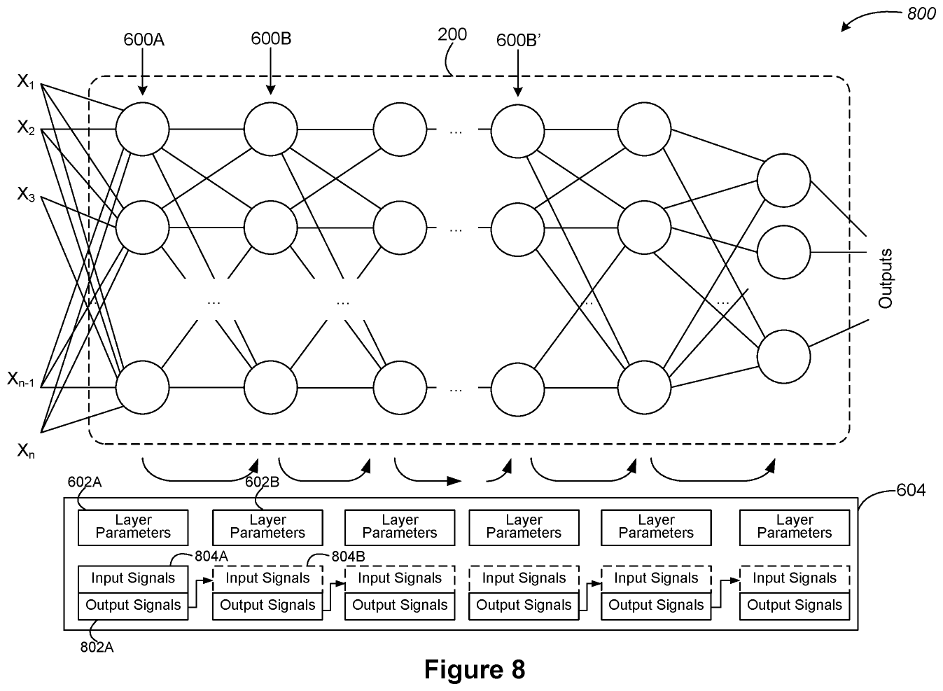

FIG. 8 is a diagram illustrating an example process 800 of implementing an example neural network 200 using a neural layer circuit 620, according to some embodiments. The neural layer circuit 620 (e.g., in FIG. 7) includes a collection of resistors 440 and a collection of amplifiers 424. The neural layer circuit 620 is configured to sequentially implement each of a plurality of layers 600 of a neural network 200. For each layer 600, resistors and amplifiers are selected from the collection of resistors 440 and the collection of amplifiers 424 to customize the neural layer circuit 620 based on a plurality of associated layer parameters 602 (e.g., parameters 602A for a first layer 600A, parameters 602B for a second layer 600B). In some embodiments, resistance values of a subset or all of the selected resistors are variable, and adjusted based on the associated layer parameters 602.

Specifically, in some embodiments, the plurality of layers 600A includes a first layer 600A and a second layer 600B (FIG. 6). A first subset of resistors are selected from the collection of resistors 440 to form the set of input resistors of the first layer 600A, and a second subset of resistors are selected from the collection of resistors 440 to form the set of input resistors of the second layer 600B. Further, in some embodiments, the set of input resistors of the first layer 600A has a different number of resistors from the set of input resistors of the second layer 600B. For example, the numbers of neurons are different in the first layer 600A and the second layer 600B. In some embodiments, the first layer 600A and the second layer 600B include the same number of neurons that are implemented with the same subset of amplifiers 424. At least one of the set of input resistors of the first layer 600A has a different resistance value from a corresponding input resistor of the second layer 600B.

In some embodiments, the first subset of resistors of the first layer 600A has a different number of resistors from the second subset of resistors of the second layer 600B, e.g., independently of whether the set of input resistors formed from the first subset of resistors of the first layer 600A has the same number or different numbers of input resistors from the set of input resistors formed from the second subset of resistors of the second layer 600B. In some embodiments, at least one of the first subset of resistors of the first layer has a different resistance value from a corresponding resistor of the second subset of resistors of the second layer, e.g., independently of the resulting input resistors.

In some embodiments, the first subset of resistors of the first layer 600A is identical to the second subset of resistors of the second layer 600B. The first subset of resistors of the first layer 600A is coupled differently from the second subset of resistors of the second layer 600B, forming a first set of input resistors of the first layer 600A that are different from a second set of input resistors of the second layer 600B.

In some embodiments, the plurality of output signals 802A of the first layer 600A are temporarily stored in the memory 604 after the neural layer circuit 620A is formed to realize the first layer 600A and generate the output signals 802A. The output signals 802A are subsequently extracted from the memory 604 when the neural layer circuit 620A is formed to realize the second layer 600B, and applied as the plurality of input signals 804B of the second layer 600B. Alternatively, in some embodiments, the plurality of output signals 802A generated by the first layer 600A are temporarily held by flip-flop registers without being stored in the memory 604. While the output signals 802A are held by the flip-flop registers, the neural layer circuit 620A is reconfigured to form the neural layer circuit 620B based on the collection of resistors 440 and the collection of amplifiers 424. The plurality of output signals 802A of the first layer 600A are applied as the plurality of input signals 804B of the second layer 600B. Similarly, the plurality of input signals 804A of the first layer 600A are optionally extracted from the memory 604 or provided by the flip-flop registers that temporarily holds the input signals 804A.

In some embodiments, referring to FIG. 8, the second layer 600B is immediately connected to and follows the first layer 600A in the neural network 200. Alternatively, in some embodiments, the second layer 600B′ is separated from the first layer 600A by at least one or more intermediate layers. In some embodiments, the collection of resistors 440 and the collection of amplifiers 424 are successively applied to implement all layers of the neuron network 200.

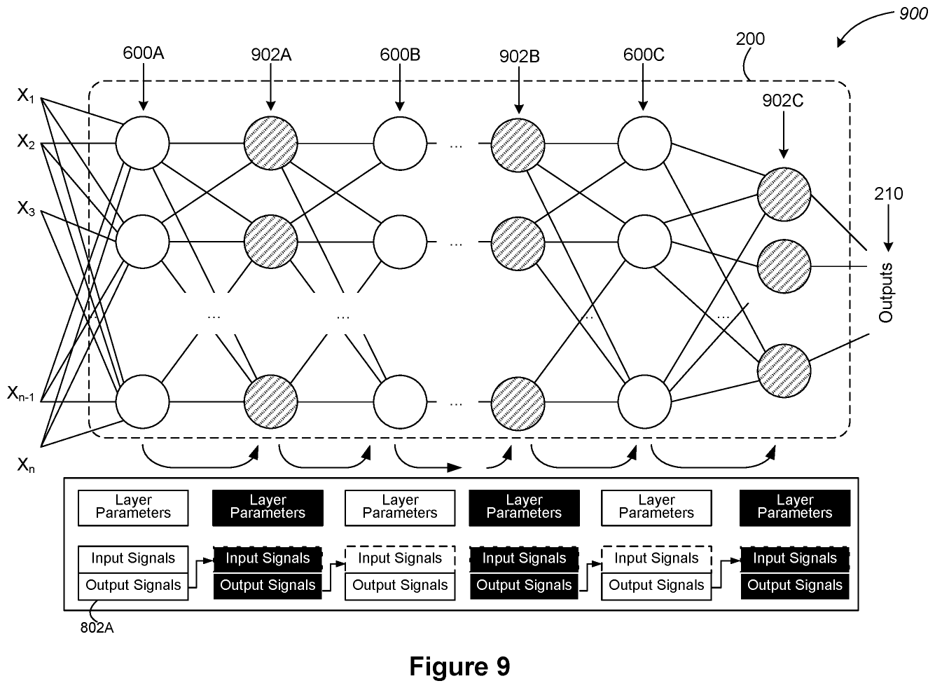

FIG. 9 is a diagram illustrating an example process 900 of implementing an example neural network 200 using two or more distinct neural layer circuits 620, according to some embodiments. The neural layer circuit 620 (e.g., in FIG. 7) includes a collection of resistors 440 and a collection of amplifiers 424. The neural layer circuit 620 is configured to sequentially implement each of a plurality of layers 600 (e.g., 600A, 600B, and 600C in FIG. 9) of a neural network 200. For each layer 600, resistors and amplifiers are selected from the collection of resistors 440 and the collection of amplifiers 424 to customize the neural layer circuit 620 based on a plurality of associated layer parameters 602 (e.g., parameters 602A for a first layer 600A, parameters 602B for a second layer 600B). The plurality of layers 600 are optionally connected to one another or separated from each other by one or more intermediate layers. In some embodiments, the neural network 200 further includes an alternative layer 902A distinct from the plurality of layers 600, and the alternative layer 902A is not implemented by the collection of resistors 440 and the collection of amplifiers 424. Further, in some embodiments, the alternative layer 902A is implemented by a distinct collection of resistors and a distinct collection of amplifiers electrically coupled to the distinct collection of resistors.

Additionally, in some embodiments, a plurality of alternative layers 902A, 902B, and 902C are realized using the distinct collection of resistors and the distinct collection of amplifiers successively, and applied with the plurality of layers 600A, 600B, and 600C in an intervening manner. While a first layer 600A is processing its input signals to generate the output signals 802A, the alternatively layer 902A is being formed by reconfiguring the distinct collection of resistors and the distinct collection of amplifiers, and processes the output signals 802A as soon as the output signals 802A are generated. In some embodiments not shown, the neural network 200 includes one or more layers 600 that are not implemented by any collection of resistors or amplifiers.

In some embodiments not shown, the neural network 200 includes a set of successive layers that are coupled to the outputs 210 of the neural network 200, and the set of successive layers are trained and customized to have variable weights. Further, in some embodiments, the set of successive layers are implemented by a single neural layer circuit 620. Alternatively, in some embodiments, the set of successive layers are implemented by two or more neural layer circuits 620, e.g., in an interleaving manner. Additionally, in some embodiments, each layer of a remainder of the set of successive layers has fixed weights and is implemented using a dedicated neural layer circuit.

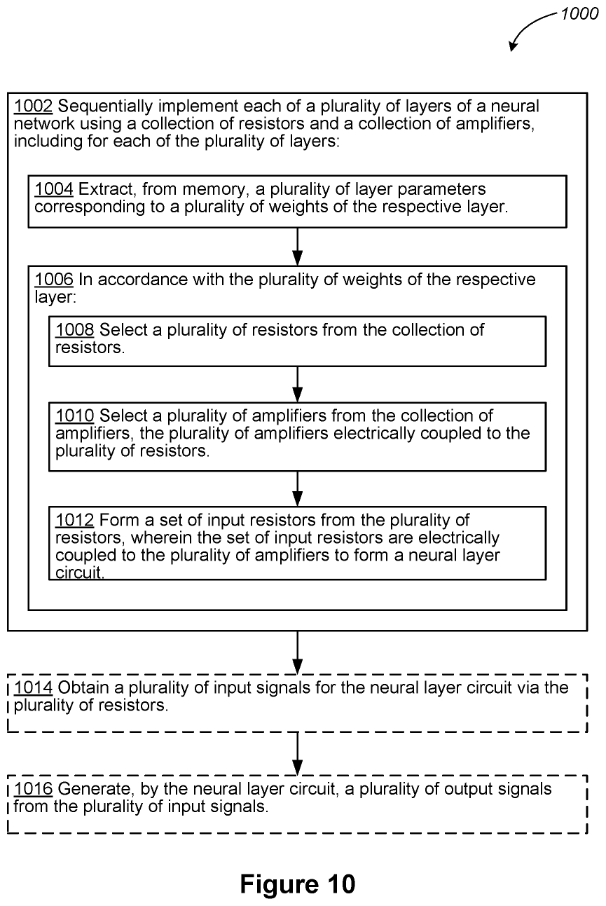

FIG. 10 is a flow diagram of a method 1000 of implementing a neural network 200 based on a neural layer circuit 620 corresponding to a single layer 600 of the neural network 200, in accordance with some embodiments. Each of a plurality of layers 600 (e.g., 600A, 600B, and 600B′ in FIG. 8) of a neural network 200 is sequentially implemented (operation 1002) using a collection of resistors 440 and a collection of amplifiers 424. For each of the plurality of layers 600, a plurality of layer parameters 602 correspond to a plurality of weights of the respective layer 600 and are extracted (operation 1004) from memory 604. In accordance with the plurality of layer parameters 602 (operation 1006), a plurality of resistors 440 are selected (operation 1008) from the collection of resistors 440, and a plurality of amplifiers 424 are selected (operation 1010) from the collection of amplifiers 424. The plurality of amplifiers 424 are electrically coupled to the plurality of resistors 440. A set of input resistors 440 are formed (operation 1012) from the plurality of resistors 440, and electrically coupled to the plurality of amplifiers 424 to form a neural layer circuit 620.

In some embodiments, a plurality of input signals (e.g., U1-UN in FIGS. 6 and 7) are provided (operation 1014) to the neural layer circuit 620 via the plurality of resistors 440. The neural layer circuit 620 generates (operation 1016) a plurality of output signals (e.g., Uₒᵤₜ₁, Uₒᵤₜ₂, . . . and U_{outM}) from the plurality of input signals. Further, in some embodiments, each of the plurality of resistors 440 has an input terminal and an alternative terminal. The set of input resistors 440 are formed for each of the plurality of layers 600. For each of the plurality of input signals, input terminals of a respective subset of the plurality of resistors 440 are electrically coupled to form a respective input interface for receiving the respective input signal. A weight of the respective input signal depends on resistance values of the respective subset of the plurality of resistors 440.

In some embodiments, the plurality of layers 600 includes a first layer 600A and a second layer 600B (FIG. 8). A first subset of resistors 440 are selected from the collection of resistors 440 to form the set of input resistors 440 of the first layer 600A, and a second subset of resistors 440 are selected from the collection of resistors 440 to form the set of input resistors 440 of the second layer 600B. Further, in some embodiments, the set of input resistors 440 of the first layer 600A has a different number of resistors from the set of input resistors 440 of the second layer 600B. In some embodiments, at least one of the set of input resistors 440 of the first layer 600A has a different resistance value from a corresponding input resistor of the second layer 600B. In some embodiments, the first subset of resistors 440 of the first layer 600A has a different number of resistors from the second subset of resistors 440 of the second layer 600B. In some embodiments, at least one of the first subset of resistors 440 of the first layer 600A has a different resistance value from a corresponding resistor of the second subset of resistors 440 of the second layer 600B. In some embodiments, the first subset of resistors 440 of the first layer 600A is identical to the second subset of resistors 440 of the second layer 600B, and is coupled differently from the second subset of resistors 440 of the second layer 600B.

Further, in some embodiments, a plurality of output signals of the first layer 600A are temporarily stored in memory 604. The plurality of output signals of the first layer 600A are extracted from the memory 604, and applied as a plurality of input signals of the second layer 600B. Alternatively, in some embodiments, a plurality of output signals of the first layer 600A are temporarily held by the first layer 600A by flip-flop registers without being stored in the memory 604. The plurality of output signals of the first layer 600A held by the flip-flop registers are applied as a plurality of input signals of the second layer 600B.

In some embodiments, the second layer 600B is immediately connected to the first layer 600A in the neural network 200. Alternatively, in some embodiments, the second layer 600B is separated from the first layer 600A by at least one or more intermediate layers 600.

In some embodiments, each of the plurality of resistors 440 has an input terminal and an alternative terminal. Each of a plurality of input signals is electrically coupled to the input terminal of a respective one of a subset of the plurality of resistors 440 for receiving the respective input signal. A weight of each input signal depends partially on a resistance value of the respective one of the subset of the plurality of resistors 440. The alternative terminal of each of the subset of the plurality of resistors 440 is coupled to an input interface of a respective amplifier.

In some embodiments, the neural network 200 further includes an alternative layer 902A (FIG. 9) distinct from the plurality of layers 600, and the alternative layer 902A is not implemented by the collection of resistors 440 and the collection of amplifiers 424. Further, in some embodiments, the alternative layer 902A is implemented by a distinct collection of resistors 440 and a distinct collection of amplifiers 424 electrically coupled to the distinct collection of resistors 440.

In some embodiments, each of the input resistors 440 has two terminals including a first terminal for receiving a respective input signal and a second terminal coupled to an input of a respective amplifier.

In some embodiments, each of the set of input resistors 440 has a respective resistance value that is defined by the plurality of layer parameters 602 to reach a predefined precision level.

In some embodiments, the plurality of resistors 440 includes a first resistor having a variable resistance. Further, in some embodiments, the first resistor includes at least one photo resistor, which is configured to be exposed to a controllable source of light, and the variable resistance of the first resistor depends on a brightness level of the controllable source of light. In some embodiments, the first resistor is configured to have a first resistance and a second resistance. In accordance with a determination that a weight of a first layer 600A has a first value, the source of light is controlled to make the first resistor provide the first resistance. In accordance with a determination that a weight of a second layer 600B has a second value, the source of light is controlled to make the first resistor provide the second resistance. Additionally, in some embodiments, the photo resistor includes one or more of: cadmium sulfide (CdS), cadmium selenide (CdSe), lead sulfide (PbS) and indium antimonide (InSb), and titanium oxide (TiO2).

In some embodiments, a subset of the plurality of resistors 440 are selected from a crossbar array 720 of resistive elements having a plurality of word lines 702, a plurality of bit lines 704, and a plurality of resistive elements 440, wherein each resistive element is located at a cross point of, and electrically coupled between, a respective word line and a respective bit line.

In some embodiments, a subset of the plurality of resistors 440 are selected from a crossbar array of NOR flash memory 604 cells having a plurality of word lines, a plurality of bit lines, and a plurality of NOR flash memory 604 cells. Each NOR flash memory 604 cell is located at a cross point of, and electrically coupled between, a respective word line and a respective bit line and configured to provide a respective NOR flash memory 604 cell as a respective resistive element.

In some embodiments, a subset of the plurality of resistors 440 are selected from a crossbar array of memristors having a plurality of word lines, a plurality of bit lines, and a plurality of memristors. Each memristor is located at a cross point of, and electrically coupled between, a respective word line and a respective bit line and configured to provide a respective one of the collection of resistors 440.

In some embodiments, a subset of the plurality of resistors 440 are selected from a crossbar array of phase-change memory 604 (PCM) memory 604 cells having a plurality of word lines, a plurality of bit lines, and a plurality of PCM memory 604 cells. Each PCM memory 604 cell is located at a cross point of, and electrically coupled between, a respective word line and a respective bit line and configured to provide a respective one of the collection of resistors 440.

In some embodiments, a subset of the plurality of resistors 440 are selected from a crossbar array of magnetoresistive memory 604 cells having a plurality of word lines, a plurality of bit lines, and a plurality of magnetoresistive memory 604 cells. Each magnetoresistive memory 604 cell is located at a cross point of, and electrically coupled between, a respective word line and a respective bit line and configured to provide a respective one of the collection of resistors 440.

The terminology used in the description of the invention herein is for the purpose of describing particular embodiments only and is not intended to be limiting of the invention. As used in the description of the invention and the appended claims, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof.

The foregoing description, for purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to best explain the principles of the invention and its practical applications, to thereby enable others skilled in the art to best utilize the invention and various embodiments with various modifications as are suited to the particular use contemplated.

What is claimed is:

1. A method, comprising:
sequentially implementing each of a plurality of layers of a neural network using a collection of resistors and a collection of amplifiers, including for each of the plurality of layers:
extracting, from memory, a plurality of layer parameters corresponding to a plurality of weights of the respective layer;
in accordance with the plurality of layer parameters:
selecting a plurality of resistors from the collection of resistors;
selecting a plurality of amplifiers from the collection of amplifiers, the plurality of amplifiers electrically coupled to the plurality of resistors; and
forming a set of input resistors from the plurality of resistors, wherein the set of input resistors are electrically coupled to the plurality of amplifiers to form a neural layer circuit.

2. The method of claim 1, further comprising:
obtaining a plurality of input signals for the neural layer circuit via the plurality of resistors; and
generating, by the neural layer circuit, a plurality of output signals from the plurality of input signals.

3. The method of claim 2, wherein each of the plurality of resistors has an input terminal and an alternative terminal, and forming the set of input resistors for each of the plurality of layers further comprises, for each of the plurality of input signals:
electrically coupling input terminals of a respective subset of the plurality of resistors to form a respective input interface for receiving the respective input signal, wherein a weight of the respective input signal depends on resistance values of the respective subset of the plurality of resistors.

4. The method of claim 1, wherein the plurality of layers includes a first layer and a second layer, and forming the set of input resistors for each of the plurality of layers further comprises:
selecting a first subset of resistors from the collection of resistors to form the set of input resistors of the first layer; and
selecting a second subset of resistors from the collection of resistors to form the set of input resistors of the second layer.

5. The method of claim 4, wherein the set of input resistors of the first layer has a different number of resistors from the set of input resistors of the second layer.

6. The method of claim 4, wherein at least one of the set of input resistors of the first layer has a different resistance value from a corresponding input resistor of the second layer.

7. The method of claim 4, wherein the first subset of resistors of the first layer has a different number of resistors from the second subset of resistors of the second layer.

8. The method of claim 4, wherein at least one of the first subset of resistors of the first layer has a different resistance value from a corresponding resistor of the second subset of resistors of the second layer.

9. The method of claim 4, wherein the first subset of resistors of the first layer is identical to the second subset of resistors of the second layer, and is coupled differently from the second subset of resistors of the second layer.

10. The method of claim 4, further comprising:
temporarily storing a plurality of output signals of the first layer in memory;
extracting the plurality of output signals of the first layer from the memory; and
applying the plurality of output signals of the first layer extracted from the memory as a plurality of input signals of the second layer.

11. The method of claim 4, further comprising:
temporarily holding a plurality of output signals generated by the first layer by flip-flop registers without being stored in the memory; and
applying the plurality of output signals of the first layer held by the flip-flop registers as a plurality of input signals of the second layer.

12. The method of claim 4, wherein the second layer is separated from the first layer by one or more intermediate layers.

13. An electronic device, comprising:
a collection of resistors;
a collection of amplifiers coupled to the collection of resistors;
a controller coupled to the collection of resistors and the collection of amplifiers, wherein the controller is configured to implement each of a plurality of layers of a neural network sequentially, including for each of the plurality of layers:
extracting, from memory, a plurality of layer parameters corresponding to a plurality of weights of the respective layer;
in accordance with the plurality of layer parameters:
selecting a plurality of resistors from the collection of resistors;
selecting a plurality of amplifiers from the collection of amplifiers, the plurality of amplifiers electrically coupled to the plurality of resistors; and
forming a set of input resistors from the plurality of resistors, wherein the set of input resistors are electrically coupled to the plurality of amplifiers to form a neural layer circuit.

14. The electronic device of claim 13, wherein each of the plurality of resistors has an input terminal and an alternative terminal, and forming the set of input resistors for each of the plurality of layers further comprises:
electrically coupling each of a plurality of input signals to the input terminal of a respective one of a subset of the plurality of resistors for receiving the respective input signal, wherein a respective weight of each input signal depends partially on a resistance value of the respective one of the subset of the plurality of resistors; and
coupling the alternative terminal of each of the subset of the plurality of resistors to a respective input interface of a respective amplifier.

15. The electronic device of claim 13, wherein the neural network further includes an alternative layer distinct from the plurality of layers, and the alternative layer is not implemented by the collection of resistors and the collection of amplifiers.

16. The electronic device of claim 15 wherein the alternative layer is implemented by a distinct collection of resistors and a distinct collection of amplifiers electrically coupled to the distinct collection of resistors.

17. The electronic device of claim 13, wherein each of the input resistors has two terminals including a first terminal for receiving a respective input signal and a second terminal coupled to an input of a respective amplifier.

18. The electronic device of claim 13, wherein each of the set of input resistors has a respective resistance value that is defined by the plurality of layer parameters to achieve a predefined precision level.

19. The electronic device of claim 13, wherein the plurality of resistors includes a first resistor having a variable resistance.

20. The electronic device of claim 13, wherein a subset of the plurality of resistors is selected from a crossbar array of resistive elements having a plurality of word lines, a plurality of bit lines, and a plurality of resistive elements, and wherein each resistive element is located at a cross point of, and electrically coupled between, a respective word line and a respective bit line.
